(19) United States
(12) Patent Application Publication
(10) Pub. No.: US 2013/0343012 A1
(43) Pub. Date: Dec. 26, 2013

(54) DISPLAY DEVICE

(71) Applicant: SAMSUNG DISPLAY CO., LTD., Yongin-city (KR)

(72) Inventor: Jin-Hee Park, Yongin-city (KR)

(73) Assignee: SAMSUNG DISPLAY CO., LTD., Yongin-city (KR)

(21) Appl. No.: 13/688,100

(22) Filed: Nov. 28, 2012

(30) Foreign Application Priority Data
Jun. 26, 2012 (KR) 10-2012-0068766

(51) Int. Cl. H05K 7/14

(52) U.S. Cl. CPC H05K 7/1417; H05K 7/1422
USPC 361/750; 361/679.01; 361/749

(57) ABSTRACT

A display device includes a set bracket having end portions bent in a predetermined angle, a display panel including a display formed on the set bracket, a bending portion integrally extended from the display and bent to correspond to a bent form of the set bracket, and a fastening portion integrally extended from the bending portion and fixed to the set bracket, and a set case configured to receive the set bracket and the display panel.

### CROSS-REFERENCE TO RELATED APPLICATIONS

This application claims priority to and the benefit of Korean Patent Application No. 10-2012-0068766 filed in the Korean Intellectual Property Office on Jun. 26, 2012, the entire contents of which are incorporated herein by reference.

### BACKGROUND

1. Field

The described technology relates generally to a display device. More particularly, the described technology relates generally to a display device having a structure that fastens a display panel to a display device set.

2. Description of the Related Technology

Nowadays, a display device set fastening structure of a general display panel is a structure that attaches window glass to a display device set by applying a double-sided adhesive tape to vertical and lateral circumferential edge portions of the window glass. Recently, in order to minimize a black matrix (BM) of the lateral portion of the window glass, by attaching a double-sided adhesive tape only to the vertical portion of the window glass and attaching a double-sided adhesive tape to a lateral portion of the display panel, an attempt of fastening the window glass to the display device set was performed. Such an attempt has an advantage, compared with an existing structure when forming the BM of the lateral portion of the window glass in a slim shape, but because a rear surface of the lateral portion of the display panel is directly attached to the display device set using a double-sided adhesive tape, when an impact such as a fall occurs, a thin film encapsulation (TFE) layer of the panel may be easily damaged.

The above information disclosed in this Background section is only for enhancement of understanding of the background of the described technology and therefore it may contain information that does not form the prior art that is already known in this country to a person of ordinary skill in the art.

### SUMMARY OF CERTAIN INVENTIVE ASPECTS

The described technology has been made in an effort to provide a display device having advantages of minimizing a BM of a lateral portion of window glass and preventing a display panel from being damaged from an external impact such as a fall by providing a structure that fastens a lateral portion of the display panel by bending to a display device set using flexible substrate characteristics of the display panel.

One embodiment provides a display device including: a set bracket having end portions bent in a predetermined angle; a display panel including a display formed on the set bracket, a bending portion integrally extended from the display and bent to correspond to a bent form of the set bracket, and a fastening portion integrally extended from the bending portion and fixed to the set bracket; and a set case configured to receive the set bracket and the display panel.

The display panel may also include a flexible substrate; a driving circuit formed on the flexible substrate and including a thin film transistor; an organic light emitting element formed on the flexible substrate and connected to the driving circuit; and an encapsulation thin film formed on the flexible substrate and covering the organic light emitting element and the driving circuit.

The display device may further include a polarizer attached to the display panel.

The display panel and the set bracket may be fastened and fixed using a fastener that penetrates between a set bracket hole formed in the bent end portions of the set bracket and a panel hole formed at a position corresponding to the set bracket hole and formed in the fastening portion of the display panel.

The bent end portions of the set bracket and the fastening portion of the display panel may closely contact and be fixed to one another by a clip.

The bent end portions of the set bracket and end portions of the set case corresponding to the bent end portions of the set bracket may have magnetism of opposite polarity, and the fastening portion of the display panel may closely contact and be fixed by magnetic attraction between end portions of the set bracket and both end portions of the set case.

An angle of a bending portion of the display panel may be about 90°.

A curvature radius of a bending portion of the display panel may be between about 0.5 mm and about 1 mm.

The flexible substrate may include a plastic material.

According to some embodiments, a BM of a lateral portion of window glass of a display device can be minimized, and a display panel can be prevented from being damaged from an external impact such as the fall.

### BRIEF DESCRIPTION OF THE DRAWINGS

FIG. 1 is a front view illustrating a display device according to a first embodiment.

FIG. 2 is a partial cross-sectional view of the display device taken along line X-X of FIG. 1.

FIG. 3 is a partial cross-sectional view illustrating the display device taken along line Y-Y of FIG. 1.

FIG. 4 is a cross-sectional view illustrating a display panel according to a first embodiment.

FIG. 5 is a diagram illustrating a display area and a BM according to a curvature radius of a display panel according to a first embodiment.

FIG. 6 is a partial perspective view illustrating a display device according to a second embodiment.

FIG. 7 is a partial perspective view illustrating a display device according to a third embodiment.

### DETAILED DESCRIPTION OF CERTAIN INVENTIVE EMBODIMENTS

The present invention will be described more fully hereinafter with reference to the accompanying drawings, in which certain embodiments of the invention are shown. As those skilled in the art would realize, the described embodiments may be modified in various different ways, all without departing from the spirit or scope of the present invention.

Further, like reference numerals generally designate like elements in several embodiments and are representatively described in the first embodiment and elements different from those of the first embodiment are described in other embodiments.

The views in the drawings are schematic views only, and are not intended to be to scale or correctly proportioned. Further, in the drawings, a size and ratio of each element are randomly represented for better understanding and ease of description, and the present invention is not limited thereto. Like reference numerals generally designate like elements throughout the specification. When it is said that any part is positioned “on” another part, it means the part is directly on the other part, or above the other part with at least one intermediate part.

Each described embodiment specifically represents one embodiment. As a result, the described embodiments may be modified in various different ways. Therefore, the embodiments are not limited to a specific form of a shown area and include, for example, a change of a form by production.

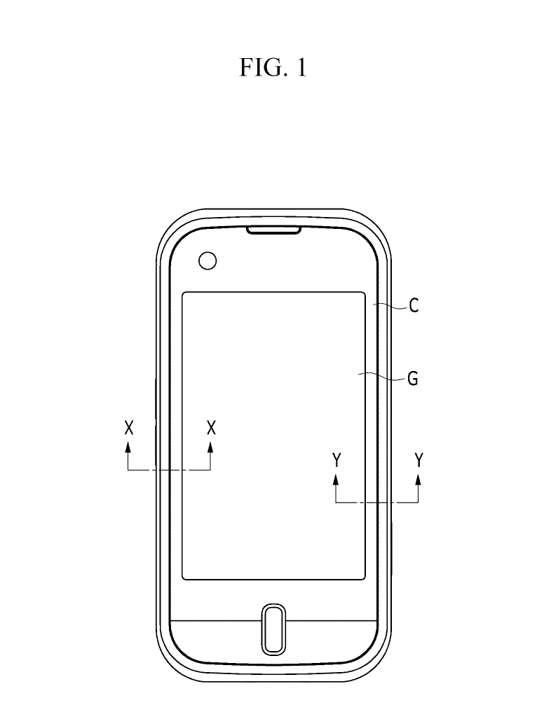

Hereinafter, a display device according to a first embodiment will be described with reference to FIGS. 1 to 3.

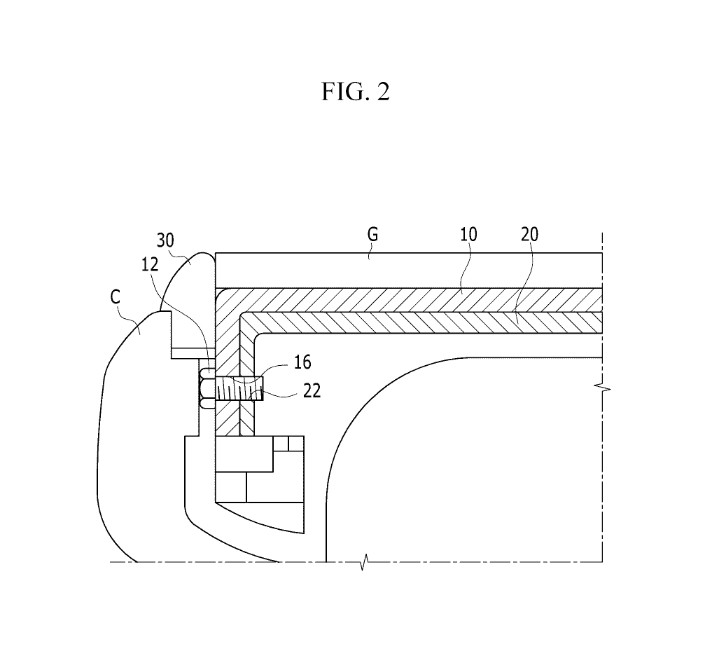

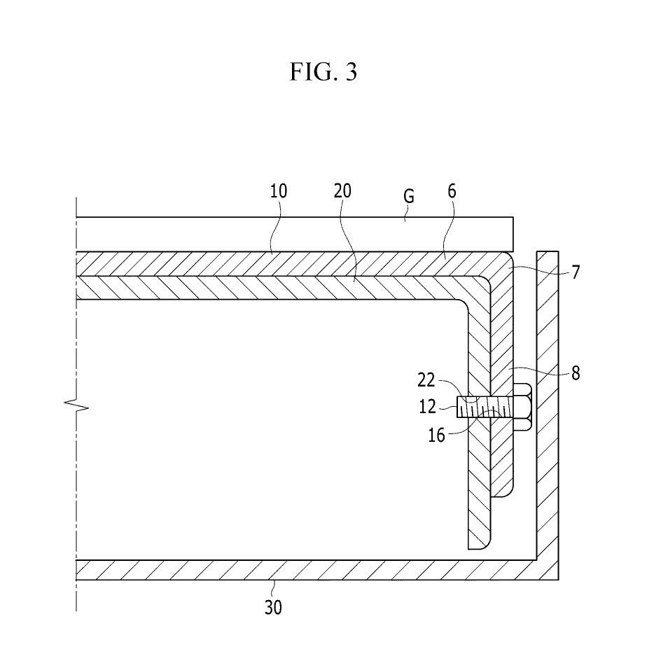

FIG. 1 is a front view illustrating a display device according to a first embodiment, FIG. 2 is a partial cross-sectional view of the display device taken along line X-X of FIG. 1, and FIG. 3 is a partial cross-sectional view illustrating the display device taken along line Y-Y of FIG. 1.

The display device includes a display panel 10, a set bracket 20, and a set case 30. A window glass G is positioned over an entire surface of an upper part of the display panel 10. The set bracket 20 is formed by bending both end portions of the left side and the right side in a lower part of the display panel 10 in a predetermined angle. A bending angle of the set bracket 20 may be about 90°. Both end portions of the display panel 10 are bent in a predetermined angle to correspond to a bent form of the set bracket 20 and are fixed to the set bracket 20. The display panel 10 may be a flexible panel. A bending angle of the display panel 10 may also be about 90°. The set case 30 houses the set bracket 20 and the display panel 10 that is fixed to the set bracket 20. Further, an external case C is provided to enclose the outside of the set case 30.

The display panel 10 includes a display 6, a bending portion 7, and a fastening portion 8. The display panel 10 close contacts on the set bracket 20, and the display 6 is formed in a horizontal portion of the set bracket 20 and displays an image. The bending portion 7 is integrally laterally extended from the display 6 and is bent in a vertical direction to correspond to a bending form of the set bracket 20. The fastening portion 8 is integrally extended from the bending portion 7 and is fastened and fixed to the set bracket 20. The display panel 10 and the set bracket 20 are fastened to each other using a fastener 12. The fastener 12 penetrates between a panel hole 16 that is formed in the fastening portion 8 and a set bracket hole 22 on the set bracket 20 that is formed at a position corresponding to the panel hole 16 and fastens and fixes the display panel 10 and the set bracket 20. The fastener 12 may be formed in a form of, for example, a bolt, and a screw thread is formed in an internal circumferential surface of the set bracket hole 22 and the panel hole 16 and an external circumferential surface of the fastener 12 and thus the internal circumferential surface and the external circumferential surface are screw-coupled. A shape and a fastening method of the fastener 12 are not limited thereto.

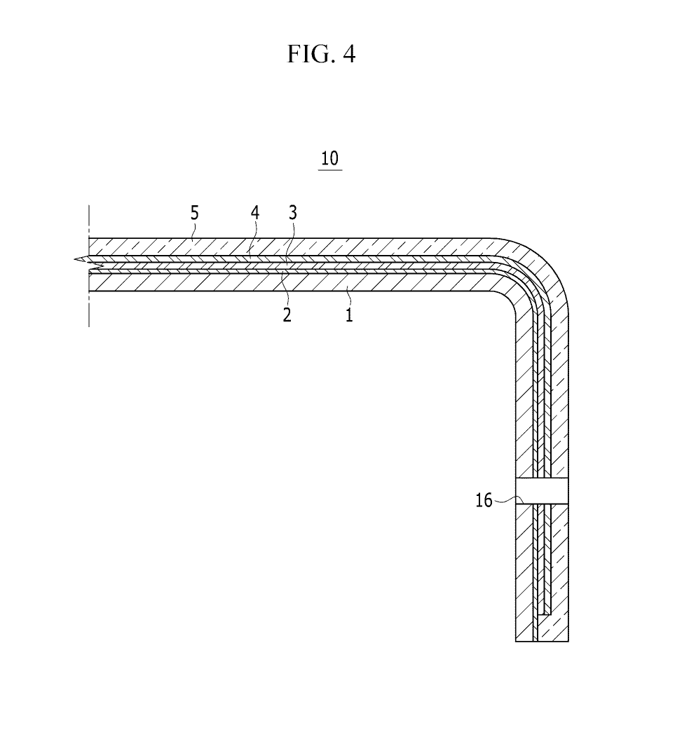

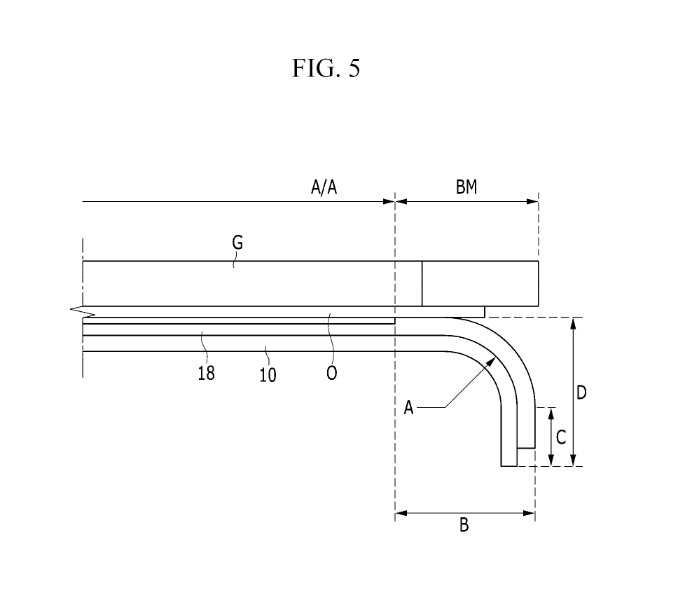

FIG. 4 is a cross-sectional view illustrating a display panel according to a first embodiment. As shown in FIG. 4, the display panel 10 includes a flexible substrate 1, a driving circuit 3, an organic light emitting element 4, and an encapsulation thin film 5. The flexible substrate 1 may be made of a plastic material, a metal substrate, or various flexible materials. The driving circuit 3 includes a thin film transistor (TFT) and drives an organic light emitting element 4. The organic light emitting element 4 is connected to the driving circuit 3 to emit light according to a driving signal that is received from the driving circuit 3, and displays an image. The encapsulation thin film 5 may be formed in a multi-layer structure and may be formed with a plurality of inorganic films or with a combination of an inorganic film and an organic film. The display panel 10 may further include a barrier film 2 that is disposed between the flexible substrate 1 and the driving circuit 3. The barrier film 2 may be formed with at least one of various inorganic films. The barrier film 2 prevents an unnecessary component such as moisture from penetrating into the organic light emitting element 4 by permeating into the flexible substrate 1. In certain embodiments, the organic light emitting element 4 is continuously formed from a display area (see A/A in FIG. 5) to the fastening portion 8 and is bent, and in the first embodiment, the organic light emitting element 4 is penetrated by the fastener 12.

FIG. 5 is a diagram illustrating an A/A and a BM according to a curvature radius of a display panel according to a first embodiment. Referring to FIG. 5, a display device according to an embodiment may further include a polarizer 18 that is attached on the display panel 10, and window glass G is attached by adhesive O on the polarizer 18. The polarizer 18 may be made of a plastic material and has flexible characteristics like the flexible substrate 1.

A curvature radius of the bending portion 7 of the display panel 10 may be set to 0.5 mm to 1 mm. When the curvature radius R of the bending portion 7 is 0.5 mm to 1 mm, a length of the BM may be 1.6 mm to 2.1 mm. A length B of the BM and other peripheral lengths A, C, and D according to a curvature radius of the bending portion 7 of the display panel 10 are shown in Table 1.

TABLE 1

| | R = 0.3 mm | R = 0.5 mm | R = 1 mm |
|---|---|---|---|
| A | 0.7 mm | 1.0 mm | 1.8 mm |
| B | 1.4 mm | 1.6 mm | 2.1 mm |
| C | 1.1 mm | 0.8 mm | 0 mm |
| D | 1.7 mm | 1.6 mm | 1.3 mm |

As shown in Table 1, for example, when a curvature radius R of a bending portion is 0.5 mm, a length A of the bending portion is 1.0 mm, a length B of the BM is 1.6 mm, a length C that is extended to a straight line from an end portion of the bending portion is 0.8 mm, and a length D that is extended to a straight line from a start point of the bending portion is 1.6 mm.

When a curvature radius R of the bending portion 7 is 0.5 mm to 1 mm, a length of the BM is 1.6 mm to 2.1 mm. When a curvature radius R of the bending portion 7 is 1 mm or more, it is difficult to fully obtain a BM slim effect, and when a curvature radius R of the bending portion 7 is 0.5 mm or less, a BM slim effect can be obtained. When an outside impact is applied, a damage probability due to TFE crack of a display panel increases when a slim effect is obtained, and thus an appropriate curvature radius R is set to 0.5 mm to 1 mm. As shown in FIG. 5, as the display panel 10 is formed in a bending form, the BM may be formed in a slim form, compared with an existing non-bending form, and the A/A can be more widely secured.

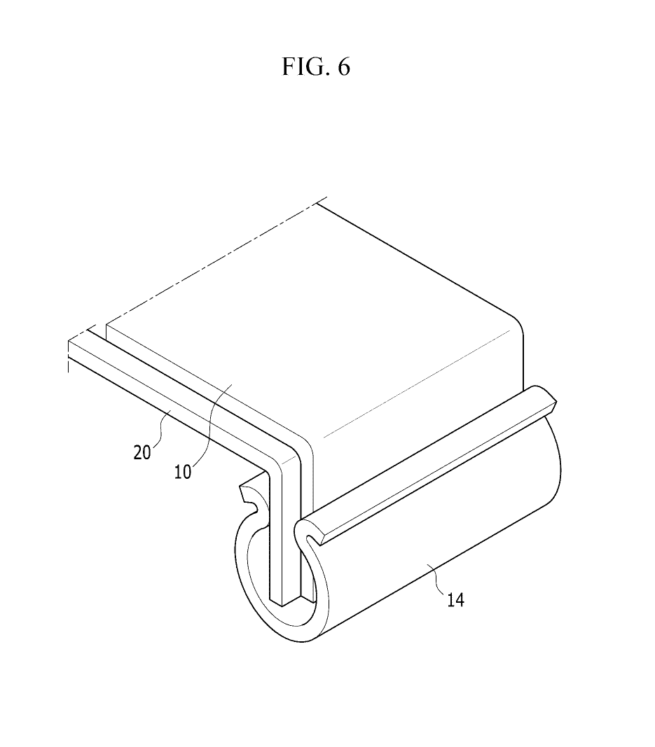

FIG. 6 is a partial perspective view illustrating a display device according to a second embodiment. Referring to FIG. 6, both end portions of the set bracket 20 are bent in a predetermined angle, and the bending portion 7 of the display panel 10 is bent in a predetermined angle to correspond to a form of the set bracket 20. A bending angle of the set bracket 20 and the display panel 10 may be about 90°. A surface of both bent end portions of the set bracket 20 and the bending portion 7 of the display panel 10 are in close contact and are fixed by a clip 14. The clip 14 has a form that is extended in a length direction in a form that encloses the close contacting set bracket 20 and the display panel 10 from a lower part. As the clip 14 has a predetermined elastic force, the clip 14 performs a function of fixing the set bracket 20 and the display panel 10 in a close contact state not to be slid or separated. The clip 14 may be formed with a section of a convex form downward extended in a length direction and a square-shaped section extended in a length direction. Further, the clip 14 may be formed in one clip 14 or a plurality of clips 14 that close contact and fix the set bracket 20 and the display panel 10 at a partial point of a surface in which the set bracket 20 and the display panel 10 close contact in addition to a form that is extended in a length direction.

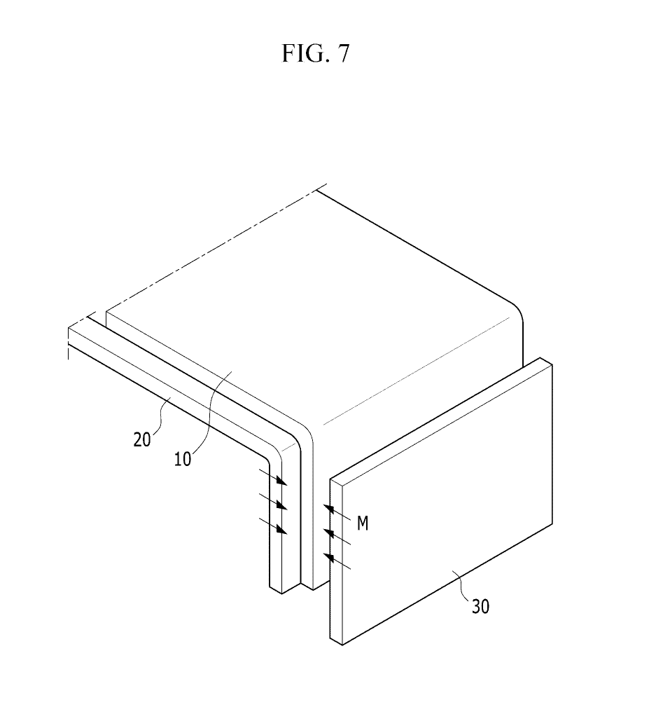

FIG. 7 is a partial perspective view illustrating a display device according to a third embodiment. Referring to FIG. 7, the display panel 10 is in close contact and is fixed by magnetism M attraction between the set bracket 20 and the set case 30. Both end portions of the set bracket 20 are bent in a predetermined angle, and both end portions of the display panel 10 are bent in a predetermined angle to correspond in a form of the set bracket 20. A bending angle of the set bracket 20 and the display panel 10 may be about 90°. The set case 30 houses the set bracket 20 and the display panel 10 that is fixed to the set bracket 20 and performs a function of closely contacting and fixing the display panel 10 by an interaction with the set bracket 20. As shown in FIG. 7, a surface of both bent end portions of the set bracket 20 and a surface of both end portions of the set case 30 corresponding to the fastening portion 8 of the set bracket 20 have magnetism M of opposite polarity, and the fastening portion 8 of the display panel 10 closely contacts and is fixed by magnetism M attraction between a surface of both end portions of the set bracket 20 and a surface of both end portions of the set case 30. The magnetism M may be formed by performing a magnetic processing at a surface of the set bracket 20 and the set case 30 of a portion in which the display panel 10 closely contacts and is fixed. In order to maintain an appropriate magnetizing force that can closely contact and fix the display panel 10 for a long period, a surface of the set bracket 20 and the set case 30 is magnetic-processed. A surface in which the set bracket 20 closely contacts with the display panel 10 and a surface in which the set case 30 closely contacts with the display panel 10 are surface-treated to have opposite magnetism and thus magnetism M attraction is formed between the set bracket 20 and the set case 30. In order for the set bracket 20 and the set case 30 to maintain a strong magnetization state for a long period, the set bracket 20 and the set case 30 may be made of a material used when manufacturing a permanent magnet. Even if electrical energy is not supplied from the outside, in order to stably maintain magnetism, the set bracket 20 and the set case 30 may be made of a material having much residual magnetism and coercivity. For example, a hardened magnet that is formed by quenching may use tungsten steel, chrome steel, and KS steel (alloy of chromium/tungsten/cobalt), and a precipitation-hardened magnet may use MK steel (alloy of iron/nickel/aluminum), alrunico (alloy of aluminum/nickel/cobalt/copper), new KS steel, and CuNiFe (alloy of copper/nickel/iron).

In this way, by a display panel fastening structure of a display device according to certain embodiments using a fastener, a clip, and magnetic attraction, a BM of a lateral portion of a window glass can be minimized and a display panel can be prevented from being damaged by an external impact such as a fall.

While this disclosure has been described in connection with certain embodiments, it is to be understood that the invention is not limited to the disclosed embodiments, but, on the contrary, is intended to cover various modifications and equivalent arrangements included within the spirit and scope of the appended claims.

Description of symbols

| | |
|---|---|
| 1: flexible substrate | 2: barrier film |
| 3: driving circuit | 4: organic light emitting element |
| 5: encapsulation thin film | 6: display |
| 7: bending portion | 8: fastening portion |
| 10: display panel | 12: fastener |

| | |
|---|---|
| 14: clip | 16: panel hole |

| | |
|---|---|
| 18: polarizer | 20: set bracket |
| 22: set bracket hole | 30: set case |
| G: window glass | C: external case |
| A/A: display area | BM: black matrix |
| M: magnetism | |

What is claimed is:

1. A display device comprising:
a set bracket having end portions bent in a predetermined angle;
a display panel comprising a display formed on the set bracket, a bending portion integrally extended from the display and bent to correspond to a bent form of the set bracket, and a fastening portion integrally extended from the bending portion and fixed to the set bracket; and
a set case configured to receive the set bracket and the display panel.

2. The display device of claim 1, wherein the display panel further comprises:
a flexible substrate;
a driving circuit formed on the flexible substrate and comprising a thin film transistor;
an organic light emitting element formed on the flexible substrate and connected to the driving circuit; and
an encapsulation thin film formed on the flexible substrate and covering the organic light emitting element and the driving circuit.

3. The display device of claim 1, further comprising a polarizer attached to the display panel.

4. The display device of claim 1, wherein the display panel and the set bracket are fastened and fixed using a fastener that penetrates between a set bracket hole formed in the bent end portions of the set bracket and a panel hole formed at a position corresponding to the set bracket hole and formed in the fastening portion of the display panel.

5. The display device of claim 1, wherein the bent end portions of the set bracket and the fastening portion of the display panel closely contact one another and are fixed to one another by a clip.

6. The display device of claim 1, wherein the bent end portions of the set bracket and end portions of the set case corresponding to the bent end portions of the set bracket have magnetism of opposite polarity, and
the fastening portion of the display panel closely contacts and is fixed by magnetic attraction between end portions of the set bracket and end portions of the set case.

7. The display device of claim 1, wherein an angle of the bending portion of the display panel is about 90°.

8. The display device of claim 1, wherein a curvature radius of the bending portion of the display panel is between about 0.5 mm and about 1 mm.

9. The display device of claim 2, wherein the flexible substrate comprises a plastic material.
